(19) United States
(12) Patent Application Publication
(10) Pub. No.: US 2025/0313949 A1
(43) Pub. Date: Oct. 9, 2025

(54) AREA SELECTIVE DEPOSITION USING METAL CARBONYL PRECURSORS

(71) Applicant: Tokyo Electron Limited, Tokyo (JP)

(72) Inventors: Robert Clark, Leuven (BE); Kai-Hung Yu, Albany, NY (US); Ryota Yonezawa, Albany, NY (US); Gyanaranjan Pattanaik, Albany, NY (US); Hidenao Suzuki, Albany, NY (US)

(21) Appl. No.: 19/096,492

(22) Filed: Mar. 31, 2025

Related U.S. Application Data
(60) Provisional application No. 63/631,168, filed on Apr. 8, 2024.

(51) Int. Cl. C23C 16/16; C23C 16/02; C23C 16/455; C23C 16/52

(52) U.S. Cl. CPC C23C 16/16; C23C 16/0272; C23C 16/45553; C23C 16/52

(57) ABSTRACT

A method for area selective deposition. The method includes providing a substrate in a process chamber, the substrate containing a growth surface and a non-growth surface, and selectively depositing a metal-containing film on the growth surface relative to the non-grown surface by exposing the substrate to a first gas flow containing carbon monoxide (CO) gas to form adsorbed CO on the substrate, and exposing the substrate to a second gas flow containing a metal carbonyl precursor, where the adsorbed CO reduces decomposition rate of the metal carbonyl precursor on the non-growth surface.

### CROSS REFERENCE TO RELATED PATENTS AND APPLICATIONS

This application claims priority to and the benefit of the filing date of U.S. Provisional Patent Application No. 63/631,168, filed Apr. 8, 2024, which application is incorporated herein by reference in its entirety.

### FIELD OF THE INVENTION

This disclosure relates to material deposition techniques including techniques for area selective deposition using metal carbonyl precursors for microelectronic devices.

### BACKGROUND OF THE INVENTION

Area selective deposition (ASD) is a technique used to selectively deposit thin films on specific areas of a substrate while leaving other areas uncoated. It can provide precise control over the spatial distribution of the deposited material, allowing for targeted and localized film growth.

### SUMMARY OF THE INVENTION

Embodiments of the invention describe a method for area selective deposition. According to one embodiment, the method includes providing a substrate in a process chamber, the substrate containing a growth surface and a non-growth surface, and selectively depositing a metal-containing film on the growth surface relative to the non-grown surface by: exposing the substrate to a first gas flow containing carbon monoxide (CO) gas to form adsorbed CO on the substrate, and exposing the substrate to a second gas flow containing a metal carbonyl precursor, where the adsorbed CO reduces decomposition rate of the metal carbonyl precursor on the non-growth surface.

According to another embodiment, the method includes providing a substrate in a process chamber, the substrate containing a growth surface and a non-growth surface, and selectively depositing a Ru metal film on the growth surface relative to the non-grown surface by: exposing the substrate to a first gas flow containing carbon monoxide (CO) gas to form adsorbed CO on the substrate, and exposing the substrate to a second gas flow formed by vaporizing triruthenium dodecacarbonyl (Ru₃(CO)₁₂) in the presence of CO carrier gas, where the adsorbed CO reduces decomposition rate of the metal carbonyl precursor on the non-growth surface, and where the first gas flow temporally overlaps with or precedes the second gas flow.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 schematically shows metal carbonyl (M(CO)ₓ) CVD without the use of excess carbon monoxide;

FIG. 2 schematically shows metal carbonyl (M(CO)ₓ) CVD with the use of excess carbon monoxide according to an embodiment of the invention;

FIGS. 3A and 3B schematically show area selective film deposition on a growth surface relative to a non-growth surface according to one embodiment;

FIGS. 4A and 4B schematically show area selective film deposition on a growth surface relative to a non-growth surface according to one embodiment;

FIG. 5 depicts a schematic view of a deposition system according to an embodiment of the invention;

FIG. 6A schematically shows gas flows during Ru metal deposition by CVD according to an embodiment of the invention; and

FIG. 6B schematically shows gas flows during cyclical Ru metal deposition according to an embodiment of the invention.

### DETAILED DESCRIPTION OF SEVERAL EMBODIMENTS

ASD techniques that can be used selectively deposit thin films on specific areas of a substrate while leaving other areas uncoated have gained significant interest in various applications, including electronics, catalysis, and nanofabrication. ASD offers the ability to precisely control the placement and properties of thin films, thereby enabling the development of advanced devices and structures. This capability is particularly valuable for fabricating advanced semiconductor devices with complex architectures and multiple materials.

ASD techniques can be applied in both chemical vapor deposition (CVD) and atomic layer deposition (ALD) processes, for example. In CVD, ASD can involve modifying the surface properties of the substrate to selectively enhance or inhibit the deposition of the desired material or film. This can be achieved by using surface treatments or functionalizing specific regions of the substrate to attract or repel the precursor gases. In ALD, ASD can involve using selective surface chemistry or functionalization. The substrate surface is modified to have different reactivity or affinity towards the precursor gases. This can be done by introducing specific functional groups or self-assembled monolayers that interact differently with the precursor gases used in ALD. As a result, the thin film deposition occurs only on the targeted areas with the desired surface modification.

ASD can be employed in various ways in semiconductor manufacturing, including for selective growth of semiconductor materials, maskless patterning, selective deposition of dielectric materials, surface modification and functionalization, metal on metal deposition, interconnect fabrication, seed layer deposition, contact formation, fabrication of metal gates, metallization patterning, and more.

Selective growth of semiconductor materials by ASD can be utilized to selectively deposit semiconductor materials on specific regions of a substrate. This is crucial for fabricating devices with heterogeneous structures, such as transistors, where different materials are required in different regions. By selectively depositing semiconductor materials, ASD allows for precise control over the active regions of the device, optimizing performance and reducing power consumption.

Maskless patterning by ASD techniques can enable maskless patterning, which eliminates the need for traditional lithographic masks. ASD can be used to selectively deposit a material in desired areas, acting as a direct patterning method. This simplifies the manufacturing process and reduces production costs associated with mask fabrication and alignment.

Selective deposition of dielectric materials by ASD can be employed for the selective deposition of dielectric materials, such as insulating layers or passivation coatings. By precisely depositing dielectrics on specific regions, ASD allows for better control over device isolation, reducing parasitic capacitance and enhancing overall device performance.

Surface modification and functionalization by ASD can be used to selectively modify or functionalize specific areas of a substrate. For example, ASD can be employed to deposit self-assembled monolayers (SAMs) or surface modifiers on targeted regions of the substrate. This enables precise control over surface properties, such as wettability or adhesion, which is crucial in various semiconductor processes, including device fabrication, interconnects, and bonding.

Metal on metal deposition by ASD refers to the selective deposition of one metal onto another metal surface, allowing for precise control over the placement and properties of the deposited metal. This technique has several utilities in semiconductor manufacturing:

Interconnect fabrication by ASD may be used to connect various components and transferring electrical signals. Metal on metal ASD can be used to selectively deposit metal films onto pre-defined metal interconnects, enabling precise control over the interconnect geometry and electrical properties. This allows for improved device performance, reduced resistance, and enhanced reliability.

Seed layer deposition by ASD, such as metal on metal ASD can be employed to selectively deposit seed layers on specific areas of a substrate. Seed layers are thin metal films that serve as nucleation sites for subsequent metal deposition. By selectively depositing seed layers, ASD facilitates controlled metal growth, especially in complex device structures requiring distinct metallization patterns.

Contact formation by ASD can include forming metal contacts that are used to establish electrical connections between different layers or components. Metal on metal ASD can be utilized to selectively deposit metal contacts onto specific regions, ensuring precise contact placement and minimizing the risk of short circuits or unwanted electrical connections.

Fabrication of metal gates by ASD can include forming metal gates that control flow of current in semiconductor transistors. Metal on metal ASD enables the selective deposition of metal gates onto specific areas of the transistor structure, ensuring precise gate placement and optimizing transistor performance.

Metallization patterning by ASD can be employed as a maskless patterning technique, allowing for the direct deposition of metal films in desired areas. This eliminates the need for lithographic masks, simplifying the manufacturing process and reducing production costs.

Embodiments of the invention provide a method for ASD of metal-containing films using metal carbonyl precursors. The ASD may be performed on a substrate containing a growth surface wherein deposition is preferred and a non-growth surface where deposition is not preferred. According to one embodiment, the method includes providing a substrate in a process chamber, the substrate containing growth surface and a non-growth surface, and selectively depositing a metal-containing film on the growth surface relative to the non-grown surface by exposing the substrate to a first gas flow containing carbon monoxide gas (CO, where the carbon monoxide molecule consists of a carbon atom that is triply bonded to an oxygen atom (C≡O)) to form adsorbed CO on the substrate, and exposing the substrate to a second gas flow containing a metal carbonyl precursor, where the adsorbed CO reduces decomposition rate of the metal carbonyl precursor on the non-growth surface. In one embodiment, the first gas flow temporally overlaps with or precedes the second gas flow. In one embodiment, the exposing the substrate to the first gas flow includes initiating the first gas flow, and stopping the first gas flow prior to initiating the second gas flow.

In some embodiments, the ASD may use Le Chatelier's principle as it relates to metal carbonyl decomposition. Le Chatelier's principle states that when a system at equilibrium is subjected to a change in conditions, it will shift in a way that minimizes the effect of that change. In the case of metal deposition by metal carbonyl decomposition in the presence of excess carbon monoxide, Le Chatelier's principle can be applied to understand how the system will respond to changes in temperature, pressure, or concentration of reactants or products.

Specifically, metal carbonyls (compounds formed by the reaction of metal with carbon monoxide) can decompose to form metal atoms and carbon monoxide gas. This reaction is usually reversible, meaning it can proceed in both the forward and reverse directions. If excess carbon monoxide is present, it means that the concentration of carbon monoxide is higher than required for the reaction to reach equilibrium. In this scenario, Le Chatelier's principle predicts that the system will shift towards the reverse reaction (towards the formation of metal carbonyls) in order to consume some of the excess carbon monoxide. On the other hand, if the concentration of carbon monoxide is reduced, the system will shift towards the forward reaction (towards the decomposition of metal carbonyls to deposit metals) in order to compensate for the decrease in reactant concentration.

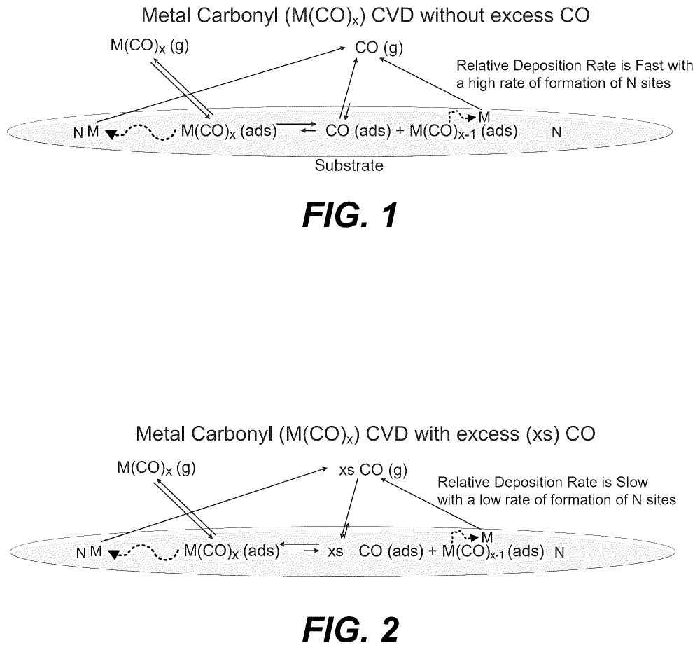

FIG. 1 schematically shows metal carbonyl (M(CO)ₓ) CVD without the use of excess carbon monoxide. M(CO)ₓ (g) in the gas phase reversibly adsorbs on the substrate surface as M(CO)ₓ (ads), and has high surface mobility. If M(CO)ₓ (ads) finds a favorable nucleation site (N) it can easily decompose by losing CO to form metal (M) on the substrate. Because the M-CO bond is weak and thermally labile, M(CO)ₓ may also lose CO reversibly on the surface. If the CO (ads) concentration on the surface is low, so is the chance to reverse the reaction by gaining back CO (ads). M(CO)ₓ₋₁ (ads) on the surface easily decomposes to metal (M) by further loss of CO, even without finding a favorable nucleation site. This creates more nucleation sites (N) on the surface.

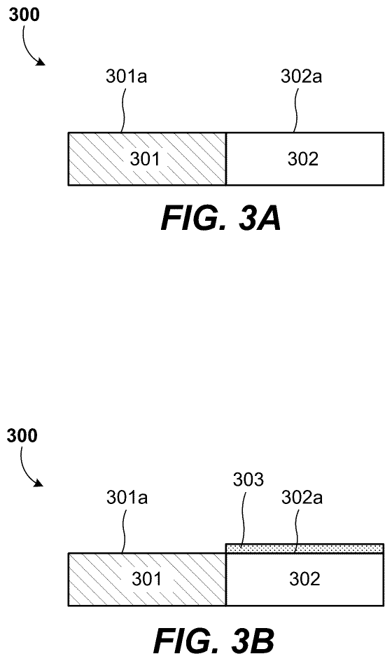

FIG. 2 schematically shows metal carbonyl (M(CO)ₓ) CVD with the use of excess carbon monoxide according to an embodiment. FIG. 2 is similar to FIG. 1, but includes providing excess (xs) CO to the process chamber. This results in the partial pressure of CO in the gas phase being high and the concentration of adsorbed CO on the substrate is increased greatly. This also results in the amount of adsorbed metal carbonyl in the form of M(CO)ₓ (ads) is increased relative to M(CO)ₓ₋₁ as a result of Le Chatelier's principle. Since the M(CO)ₓ (ads) has a high surface mobility and low deposition probability unless it finds a favorable nucleation site, the metal film growth rate is reduced (versus the CO deficient case) and becomes more island-like.

As used herein, a growth surface refers to a material surface containing a large number of nucleation sites and metal film deposition from metal carbonyls readily takes place. Further, a non-growth surface refers to a material surface containing a low number of nucleation sites and metal film deposition from metal carbonyls does not readily takes place. According to embodiments, providing excess CO during metal carbonyl deposition, the metal carbonyl on the substrate will be less likely to be CO-deficient, and the surface mobility and lifetime of the metal carbonyl on the surface of the non-growth surface is therefore increased. Further, CO may also act to passivate surface defects that could otherwise act as additional nucleation sites, the deposition rate on the non-growth surface is therefore greatly reduced. However, the metal (M) deposition rate on the growth surface is only slightly reduced as the growth are comprises a plurality of active nucleation sites (N). Therefore, by providing excess CO during metal carbonyl deposition, overall selectivity on a growth surface relative to a non-growth surface is greatly improved.

According to an embodiment, the method may further include exposing the substrate to an inhibitor gas flow prior to exposing the substrate to the metal carbonyl precursor, where the inhibitor gas contains a small molecule inhibitor (SMI) or a self-assembled monolayer precursor that further improves the area selective deposition. Examples of SMI includes hydrogen, hydrazine, oxygen, ammonia, ozone, hydrogen peroxide, water, silane, disilane, trisilane, methane, or mixtures thereof. According to one embodiment, the method may further include exposing the substrate to a halogen-containing catalyst that can further improve area selective deposition. The halogen-containing catalyst adsorbs on a growth surface prior to inhibitor gas flow and promotes the deposition of a metal-containing film on the growth surface. Examples of the halogen-containing catalyst include I₂, CH₃I, and C₂H₅I.

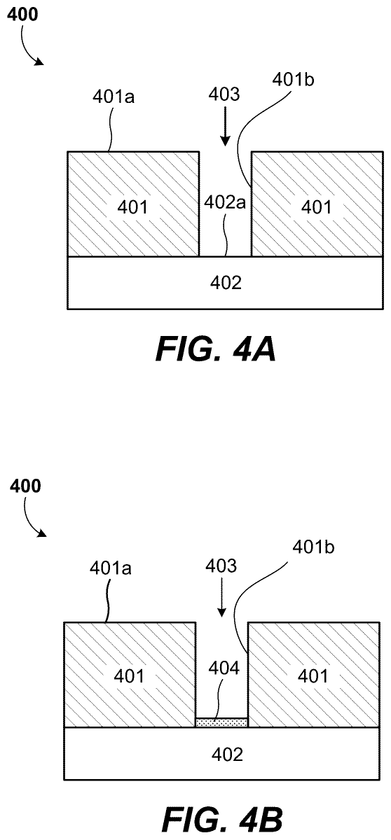

FIGS. 3A and 3B schematically show area selective deposition on a growth surface relative to a non-growth surface according to one embodiment.

FIG. 3A shows a substrate 300 containing a first material 301 having a first surface 301a and a second material 302 having a second surface 302a. The first surface 301a may also be referred to as a non-growth surface and the second surface 302a may be referred to as a growth surface. Embodiments of the invention describe a method for selectively depositing a film onto the second surface 302a relative to the first surface 301a. The first surface 301a and the second surface 302a may be in the same horizontal plane, for example after a planarization process, but this is not required and the first surface 301a and the second surface 302a may have different relative orientations or be at different heights than schematically shown in FIG. 3A. The first material 301 and the second material 302 have different chemical composition and the first surface 301a and the second surface 302a also have different chemical composition. In one embodiment, the first material 301 is a dielectric material or a semiconductor material, and the second material 302 is a metal or a metal-containing material. Examples of dielectric materials include SiO₂, SiN, SiOCN, SiOC, BN, SiBCN, and SiCN. Examples of metal and metal containing materials include Ru, Cu, W, Al, Co, Mo, TiN, TaN, NbN, Ni, Pd, Pt, Ag, and Au.

FIG. 3B shows the substrate 300 following area selective deposition of a metal-containing film 303 on the second surface 302a of the second material 302 relative to first surface 301a of the first material 301. The deposition process includes exposing the substrate to a first gas flow containing carbon monoxide (CO) gas to form adsorbed CO on the substrate, and exposing the substrate to a second gas flow containing a metal carbonyl precursor, where the adsorbed CO reduces decomposition rate of the metal carbonyl precursor on the non-growth surface. In one embodiment, the first gas flow temporally overlaps with or precedes the second gas flow. In one embodiment, the exposing the substrate to the first gas flow includes initiating the first gas flow, and stopping the first gas flow prior to initiating the second gas flow. The first gas flow containing CO gas provides excess CO gas that interacts with the surfaces as described above in FIG. 2, and improves the area selective deposition on the second surface 302a.

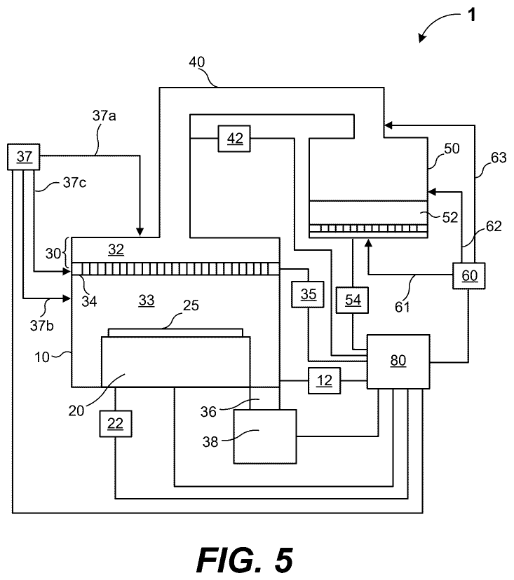

FIGS. 4A and 4B schematically show area selective deposition on a growth surface relative to a non-growth surface according to one embodiment.

FIG. 4A shows a substrate 400 including a patterned first material 401 containing a recessed feature 403 that exposes a second surface 402a of a second material 402 at the bottom of the recessed feature. The patterned first material 401 has a first surface 401a that may be horizontal (e.g., a field area) and a first surface 401b that includes a sidewall of the recessed feature 403. The first surfaces 401a and 401b may also be referred to as non-growth surfaces and the second surface 402a may be referred to as a growth surface. Embodiments of the invention describe a method for selectively depositing a film (e.g., a metal-containing film) onto the second surface 402a relative to the first surfaces 401a and 401b. The first material 401 and the second material 402 have different chemical composition and the first surfaces 401a, 401b and have different chemical composition the second surface 402a. In one embodiment, the first material 401 is a dielectric material or a semiconductor material, and the second material 402 is a metal or a metal-containing material.

FIG. 4B shows the substrate 400 following selective deposition of a metal-containing film 404 on the second surface 402a of the second material 402 relative to first surfaces 401a, 401b of the first material 401. The deposition process includes exposing the substrate to a second gas flow containing a metal carbonyl precursor, where the adsorbed CO reduces decomposition rate of the metal carbonyl precursor on the non-growth surface. In one embodiment, the first gas flow temporally overlaps with or precedes the second gas flow. In one embodiment, the exposing the substrate to the first gas flow includes initiating the first gas flow, and stopping the first gas flow prior to initiating the second gas flow. The first gas flow containing CO gas provides excess CO gas that interacts with the surfaces as described above in FIG. 2, and improves the area selective deposition on the second surface 402a.

Embodiments of the invention may be applied to substrates defining recessed features to receive a deposition of material such as a metal. The recessed features can, for example, include trenches or vias. The recessed feature diameter can be less than 100 nm, less than 50 nm, less than 30 nm, less than 20 nm, less than 10 nm, or less than 5 nm. A depth of the recessed features can, for example be greater 20 nm, greater than 50 nm, greater than 100 nm, or greater than 200 nm. The recessed features can, for example, have an aspect ratio (AR, depth: width) between 2:1 and 20:1, between 2:1 and 10:1, or between 2:1 and 5:1.

Some organometallic compounds, also known as “sigma-bonded” organometallic compounds, are characterized by the presence of a direct sigma bond between a metal center and a carbon atom of an organic ligand. In these compounds, the metal donates electron density to the organic ligand through a sigma bond. Typically the metal in the complex will be found in a low (+1 or −1) or zero oxidation state. Metal carbonyls are a class of organometallic compounds consisting of metal atoms bonded to carbon monoxide (CO) ligands. They are characterized by the presence of metal-carbon bonds and are named based on the metal atom and the number of CO ligands attached.

Metal carbonyls, such as ruthenium pentacarbonyl (Ru(CO)₅), iron pentacarbonyl (Fe(CO)₅), and nickel tetracarbonyl (Ni(CO)₄), are examples of organometallic compounds. In these compounds, the metal atom (Ru, Fe or Ni) forms direct sigma bonds with the carbon monoxide (CO) ligands. In the case of ruthenium pentacarbonyl (Ru(CO)₅), iron pentacarbonyl (Fe(CO)₅) and nickel tetracarbonyl (Ni(CO)₄) the metal centers are in the zero oxidation state, just as in ruthenium, iron or nickel metal. In general, the metal carbonyls can include Mₓ(CO)_{y} where M is a metal, x≥1 and y>1, or Mₓ(CO)_{y}L_{z} where M is a metal, x≥1, y>1, z≥1 and L is a ligand.

Some examples of volatile metal carbonyls include iron pentacarbonyl (Fe(CO)₅), nickel tetracarbonyl (Ni(CO)₄), manganese hexacarbonyl (Mn₂(CO)₁₀), chromium hexacarbonyl (Cr(CO)₆), tungsten hexacarbonyl (W(CO)₆), molybdenum hexacarbonyl (Mo(CO)₆), cobalt tetracarbonyl (Co(CO)₄), ruthenium pentacarbonyl (Ru(CO)₅), rhodium hexacarbonyl (Rh₆(CO)₁₆), platinum hexacarbonyl (Pt(CO)₆), triruthenium dodecacarbonyl (Ru₃(CO)₁₂), cobalt tricarbonyl nitrosyl (Co(CO)₃(NO), Ru(CO)₃ (1-Methyl-1,4-cyclohexadiene), Ru(CO)₃ (1-Ethyl-1,4-cyclohexadiene), or Ru(CO)₃(1-Propyl-1,4-cyclohexadiene).

The metal carbonyls above may be used to deposit the metal atoms contained in the metal carbonyls, including Fe, Ni, Mn, Cr, W, Mo, Co, Ru, Rh, and Pt. The deposited films may consist of pure metals or metal-containing materials such as metal oxides, metal oxynitrides, metal nitrides, metal carbides, and others.

While these are some commonly known volatile metal carbonyls, there may be additional compounds that are also volatile and contain metal-carbon monoxide bonds. The volatility of metal carbonyls can vary depending on factors such as the metal's electronic structure, coordination environment, and temperature.

Metal carbonyls can be formed by the reaction of metal atoms or metal complexes with carbon monoxide gas. The CO ligands coordinate to the metal atom through the carbon atom. The metal-carbon bond is primarily a sigma bond, resulting from the overlap of the metal's d-orbitals with the carbon's sp-hybridized orbital. This sigma bond forms the primary interaction between the metal center and the ligand. In addition, there is often a weaker pi backbonding interaction from the metal to the CO's antibonding molecular orbital.

Metal carbonyls can exist as solids, liquids, or gases, depending on the specific compound and its physical properties. The presence of metal-carbon sigma bonds in metal carbonyls gives rise to several important characteristics and reactivity patterns. Metal carbonyls often exhibit high volatility due to the weak nature of the metal-carbon bond, allowing them to easily undergo thermal decomposition and release carbon monoxide gas. Additionally, the sigma bond between the metal and the carbonyl ligand enables the formation of pi backbonding, where the metal's d-orbitals interact with the pi*-antibonding orbitals of the CO ligand.

The 18-electron rule is a guideline used in coordination chemistry to predict the stability and reactivity of transition metal complexes, including metal carbonyls. It states that stable transition metal complexes tend to have 18 valence electrons surrounding the central metal atom. In the context of metal carbonyls, the 18-electron rule helps determine the preferred coordination number and ligand environment for the metal center. The rule suggests that the metal atom in a metal carbonyl complex should have a total of 18 valence electrons from its own d orbitals and the ligands bound to it. To apply the 18-electron rule, the valence electron count for the metal atom and the ligands in the metal carbonyl complex is considered. The metal atom contributes its valence electrons from the d orbitals, while each CO ligand contributes two electrons from the carbon and oxygen atoms.

For example, in the case of iron pentacarbonyl (Fe(CO)₅), iron (Fe) is in the 8th group of the periodic table and has 8 valence electrons. Each CO ligand contributes 2 electrons, giving a total of 10 electrons. Therefore, Fe(CO)₅ has a total of 8+10=18 valence electrons, satisfying the 18-electron rule.

The 18-electron rule suggests that metal carbonyl complexes with 18 valence electrons tend to be more stable and less reactive. Complexes with fewer than 18 electrons may be more reactive and prone to undergo reactions to attain the stable 18-electron configuration. Conversely, complexes with more than 18 electrons may be less common or unstable due to electron-electron repulsion.

It is important to note that while the 18-electron rule is a useful guideline, there are exceptions and variations depending on the specific metal, ligands, and coordination environment. Other factors such as steric effects, electronic interactions, and ligand properties can also influence the stability and reactivity of metal carbonyl complexes.

Atomic layer deposition (ALD) and chemical vapor deposition (CVD) are two distinct but related thin film deposition techniques. CVD is a process in which thin films are formed by the chemical reaction of precursor gases on a substrate surface. It involves the simultaneous exposure of the substrate to precursors that react and deposit the desired material. CVD can be used to deposit films with a wide range of thicknesses, from nanometers to micrometers or even thicker.

On the other hand, ALD is a more controlled and precise thin film deposition technique that operates on a layer-by-layer basis. ALD utilizes sequential, self-limiting reactions to deposit thin film layers with atomic-level control over film thickness and uniformity. Each cycle of ALD consists of alternating, well-controlled pulses of reactant gases that chemically react with the substrate surface, resulting in the deposition of a monolayer of material. The self-limiting nature of ALD ensures that only about one atomic layer is deposited per cycle, allowing for precise control over film thickness.

Although ALD and CVD are different in their operation, they share common principles and can be considered as complementary techniques. Both techniques involve the use of precursor gases and chemical reactions to deposit thin films. The choice of technique depends on the specific requirements of the application.

CVD is often preferred for rapid deposition of thicker films or when conformal coating is required on complex geometries. It is suitable for applications where precise control of film thickness is not critical. ALD, on the other hand, excels in applications that require precise control over film thickness, excellent conformality, and precise film composition. It is commonly used in the semiconductor industry, where uniform and controlled film growth is crucial for device performance.

Metal carbonyls can be utilized in the atomic layer deposition (ALD) process to deposit metal-containing films with precise control over film thickness and uniformity. In ALD using metal carbonyls, the metal carbonyl precursor gas is introduced into the reaction chamber, along with a co-reactant gas, typically a reducing agent such as hydrogen or a metal-organic compound. The metal carbonyl precursor gas is typically heated to a temperature where it readily decomposes, releasing metal atoms and carbon monoxide gas.

The advantage of using metal carbonyls in ALD is that they provide a source of metal atoms with well-controlled reactivity. The precise control over the deposition process allows for the growth of high-quality metal films with uniform thickness and excellent conformality on complex substrate geometries. It is important to note that the ALD process using metal carbonyls requires careful control of temperature, pressure, and exposure times to ensure the desired film growth and prevent unwanted reactions or decomposition of the metal carbonyl precursor.

Le Chatelier's principle can also be applied to changes in temperature and pressure. For example, if the temperature is increased, the system will shift in the endothermic direction to absorb some of the added heat. Similarly, if the pressure is increased, the system will shift towards the side with fewer moles of gas to reduce the pressure. Overall, Le Chatelier's principle explains how the metal carbonyl decomposition reaction in the presence of excess carbon monoxide will respond to changes in conditions to maintain equilibrium.

During the CVD process, the metal carbonyl precursor is introduced into a reaction chamber along with a carrier gas, such as carbon monoxide, hydrogen, argon, helium or nitrogen or mixtures thereof. The metal carbonyl precursor gas may be heated to temperatures ranging from room temperature to 200-300 degrees Celsius. And the substrate is typically maintained between about 30-550 degrees Celsius. At these temperatures, the metal carbonyl decomposes, releasing metal atoms that form a film on a substrate and carbon monoxide gas. Further, during the CVD process, a gas pressure below about 15 Torr may be maintained in the process chamber.

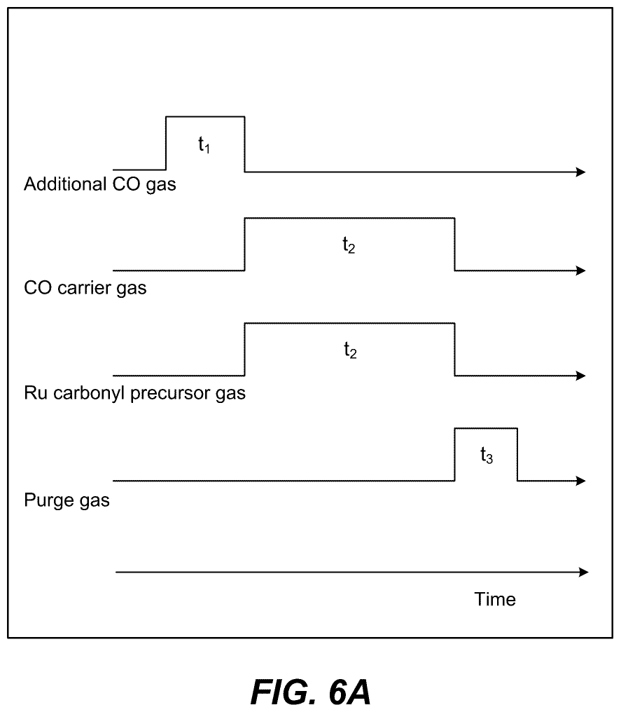

FIG. 5 depicts a schematic view of a deposition system according to an embodiment of the invention. An exemplary deposition system for depositing Ru metal from a Ru carbonyl precursor is described but the deposition system may also be used to deposit other metals from metal carbonyl precursors. The following sections describe the use of Ru₃(CO)₁₂, however other ruthenium carbonyl precursors may be used without departing from the scope of the invention. The deposition system 1 includes a process chamber 10 having a substrate holder 20 configured to support a substrate 25 upon which the Ru metal film is formed. The process chamber 10 is coupled to a metal precursor vaporization system 50 via a vapor precursor delivery system 40.

The process chamber 10 is further coupled to a vacuum pumping system 38 through a duct 36, wherein the vacuum pumping system 38 is configured to evacuate the process chamber 10, vapor precursor delivery system 40, and metal precursor vaporization system 50 to a pressure suitable for forming the Ru metal film on the substrate 25, and suitable for vaporization of the Ru carbonyl precursor 52 in the metal precursor vaporization system 50.

The metal precursor vaporization system 50 is configured to store a Ru carbonyl precursor 52, to heat the Ru carbonyl precursor 52 to a temperature sufficient for vaporizing the Ru carbonyl precursor 52, and to introduce Ru carbonyl precursor vapor to the vapor precursor delivery system 40. Ru₃(CO)₁₂ is a solid under the selected heating conditions in the metal precursor vaporization system 50, however, those skilled in the art will appreciate that other ruthenium carbonyl precursors that are liquids under the selected heating conditions can be used without departing from the scope of the invention. Although not shown, the vapor precursor delivery system 40 can include one or more control valves, one or more filters, and a mass flow controller.

In order to achieve the desired temperature for subliming the solid Ru carbonyl precursor 52, the metal precursor vaporization system 50 is coupled to a vaporization temperature control system 54 configured to control the vaporization temperature. For instance, the temperature of the Ru carbonyl precursor 52 may be elevated to between approximately 70° C. to approximately 100° C., or higher, in order to sublime the Ru₃(CO)₁₂. In one example, temperature of the Ru carbonyl precursor 52 may be elevated to between approximately 78° C. to approximately 82° C. in order to sublime the Ru₃(CO)₁₂. As the Ru carbonyl precursor 52 is heated to cause sublimation, a CO gas carrier gas can be passed over or through the Ru carbonyl precursor 52, or any combination thereof. The CO carrier gas contains CO and optionally an inert carrier gas, such as N₂, or a noble gas (i.e., He, Ne, Ar, Kr, or Xe), or a combination thereof.

For example, a gas supply system 60 is coupled to the metal precursor vaporization system 50, and it is configured to, for instance, supply CO gas, an inert gas, or a mixture thereof, beneath the Ru carbonyl precursor 52 via feed line 61, or over the Ru carbonyl precursor 52 via feed line 62. In addition, or in the alternative, the gas supply system 60 is coupled to the vapor precursor delivery system 40 downstream from the metal precursor vaporization system 50 to supply the gas to the vapor of the Ru carbonyl precursor 52 via feed line 63 as or after it enters the vapor precursor delivery system 40. Although not shown, the gas supply system 60 can comprise a CO gas source, an inert gas source, one or more control valves, one or more filters, and a mass flow controller. For instance, the flow rate of the CO carrier gas can be between about 0.1 standard cubic centimeters per minute (sccm) and about 1000 sccm. Alternately, the flow rate of the CO carrier gas can be between about 10 sccm and about 500 sccm. Still alternately, the flow rate of the CO carrier gas can be between about 50 sccm and about 300 sccm. According to embodiments of the invention, the flow rate of the CO gas can range from approximately 0.1 sccm to approximately 1000 sccm. Alternately, the flow rate of the CO gas can be between about 1 sccm and about 500 sccm.

Downstream from the metal precursor vaporization system 50, the process gas containing the Ru carbonyl precursor vapor and the CO carrier gas flows through the vapor precursor delivery system 40 until it enters the process chamber 10 via a vapor distribution system 30 coupled thereto. The vapor precursor delivery system 40 can be coupled to a vapor line temperature control system 42 in order to control the vapor line temperature and prevent decomposition of the Ru carbonyl precursor vapor as well as condensation of the Ru carbonyl precursor vapor. Although not shown, the vapor precursor delivery system 40 can include one or more control valves, one or more filters, and a mass flow controller.

The vapor distribution system 30, which forms part of and is coupled to the process chamber 10, comprises a vapor distribution plenum 32 within which the vapor disperses prior to passing through a vapor distribution plate 34 and entering a processing zone 33 above substrate 25. In addition, the vapor distribution plate 34 can be coupled to a distribution plate temperature control system 35 configured to control the temperature of the vapor distribution plate 34.

Once the process gas containing the Ru carbonyl precursor vapor enters the processing zone 33 of process chamber 10, the Ru carbonyl precursor vapor thermally decomposes upon adsorption at the substrate surface due to the elevated temperature of the substrate 25, and a Ru metal layer is formed on the substrate 25. The substrate holder 20 is configured to elevate the temperature of the substrate 25 by virtue of the substrate holder 20 being coupled to a substrate temperature control system 22. For example, the substrate temperature control system 22 can be configured to elevate the temperature of the substrate 25 up to approximately 500° C. In one example, the temperature of the substrate 25 can be maintained between about 150° C. and about 250° C. during Ru metal deposition. In another example, the temperature of the substrate 25 can be maintained between about 190° C. and about 200° C. during Ru metal deposition. Additionally, the process chamber 10 can be coupled to a chamber temperature control system 12 configured to control the temperature of the chamber walls.

The CO gas in the CO carrier gas is used to reduce premature decomposition of the Ru carbonyl precursor vapor prior to entering the process chamber 10, including in the metal precursor vaporization system 50, the vapor precursor delivery system 40, and the vapor distribution system 30. The addition of the CO gas to the Ru carbonyl precursor vapor allows for increasing the vaporization temperature from approximately 40° C. to approximately 100° C., or higher. The elevated temperature increases the vapor pressure of the ruthenium carbonyl precursor, resulting in increased delivery of the Ru carbonyl precursor to the process chamber 10 and, hence, increased deposition rate of the Ru metal on the substrate 25.

The deposition system 1 contains an additional gas source 37 coupled to the process chamber 10. The additional gas source 37 is configured to add an additional gas to the process gas containing the metal-carbonyl precursor vapor and the CO gas. According to an embodiment of the invention, the additional gas can contain an inert gas (e.g., N₂, a noble gas (i.e., He, Ne, Ar, Kr, or Xe), or a combination thereof), a CO gas, or a combination thereof. When the additional gas includes CO gas it may be referred to as excess CO gas. The additional gas source 37 can be coupled to the vapor distribution system 30 via feed line 37a and configured to add the additional gas to the process gas in the vapor distribution plenum 32 before the process gas passes through the vapor distribution plate 34 into the processing zone 33. Alternately, the additional gas source 37 can be coupled to the process chamber 10 via feed line 37b and configured to add the additional gas to the process gas in the processing zone 33 above the substrate 25 in the process chamber 10 after the process gas passes through the vapor distribution plate 34. Still alternately, the additional gas source 37 can be coupled to the vapor distribution system 30 via feed line 37c and configured to add the additional gas to the process gas in the vapor distribution plate 34.

As will be appreciated by those skilled in the art, the additional gas can be added to the process gas at other locations in the vapor distribution system 30 and the process chamber 10 without departing from the scope of the invention. According to embodiments of the invention, the additional gas can be utilized to control the CO partial pressure in the process chamber 10. A partial pressure is the pressure that a component of a gaseous mixture would have if it alone occupied the same volume at the same temperature as the mixture. The CO partial pressure in the process chamber is calculated from the relative CO gas flow (e.g., CO gas flow divided by the combined inert gas and CO gas flow). According to one embodiment, the additional gas can be utilized to flow additional CO gas to the process gas in the processing zone 33 above the substrate 25 in the process chamber 10 after the process gas passes through the vapor distribution plate 34. According to embodiments of the invention, a flow rate of the additional CO gas can range from approximately 10 sccm to approximately 1000 sccm. Alternately, the flow rate of the additional CO gas can be between about 100 sccm and about 300 sccm.

Still referring to FIG. 5, the deposition system 1 can further include a control system 80 configured to operate and control the operation of the deposition system 1. The control system 80 is coupled to the process chamber 10, the substrate holder 20, the substrate temperature control system 22, the chamber temperature control system 12, the vapor distribution system 30, the vapor precursor delivery system 40, the metal precursor vaporization system 50, the vaporization temperature control system 54, and the gas supply system 60.

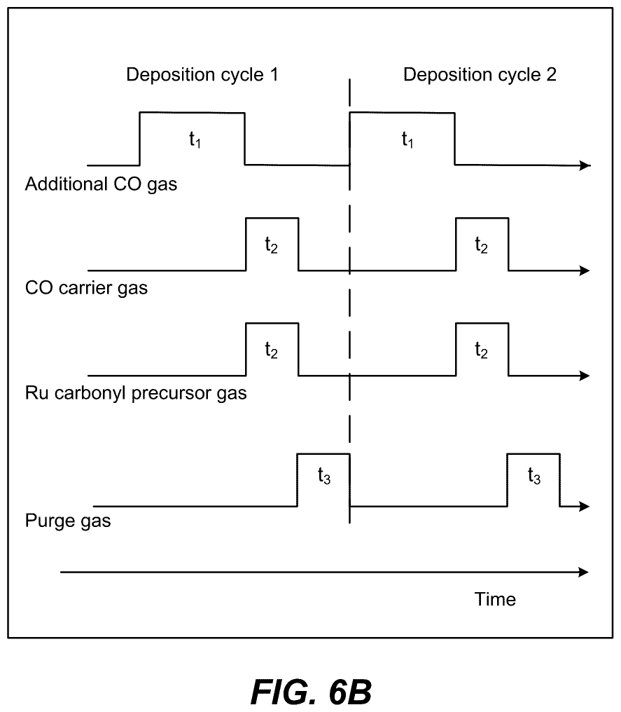

FIG. 6A schematically shows gas flows during Ru metal deposition by CVD according to an embodiment of the invention. The deposition process includes the use of a process gas containing CO carrier gas and a Ru carbonyl precursor gas, and an additional (excess) CO gas. The deposition process includes flowing the additional CO gas for a time period t₁, and, thereafter, flowing the CO carrier gas and the Ru carbonyl precursor gas for a time period t₂.

In the embodiment schematically shown in FIG. 6A, the additional CO gas flow precedes the flow of the Ru carbonyl precursor gas and the CO carrier gas. However, in other embodiments the additional CO gas flow may temporally overlap with the flow of the Ru carbonyl precursor gas and the CO carrier gas. In one embodiment, the additional CO gas flow may be continuous from before the initiation of the flow of the Ru carbonyl precursor gas and the CO carrier gas until the end of the deposition process.

A purge gas is flowed for a time period t₃ to purge or clear out the Ru carbonyl precursor from the process chamber. The additional CO gas and the purge gas may be provided by more than one gas line in the process chamber. According to one embodiment, a flow rate of the additional CO gas can be greater than the flow of the purge gas.

FIG. 6B schematically shows gas flows during cyclical Ru metal deposition according to an embodiment of the invention. The cyclical deposition process includes a plurality of deposition cycles that use a process gas containing CO carrier gas and a Ru carbonyl precursor gas, and an additional (excess) CO gas. The cyclical deposition process includes flowing the additional CO gas for a time period t₁, and flowing the CO carrier gas and the Ru carbonyl precursor gas for a time period t₂. Two of deposition cycles are shown, but the process may use any number of cycles, for example only one cycle, two cycles, or greater than two cycles.

In the embodiment schematically shown in FIG. 6B, the additional CO gas flow precedes the flow of the Ru carbonyl precursor gas and the CO carrier gas. However, in other embodiments the additional CO gas flow may temporally overlap with the flow of the Ru carbonyl precursor gas and the CO carrier gas. In one embodiment, the additional CO gas flow may be continuous from before the initiation of the flow of the Ru carbonyl precursor gas and the CO carrier gas until the end of the deposition process.

A purge gas is flowed for a time period t₃ to purge or clear out the Ru carbonyl precursor from the process chamber. The additional CO gas and the purge gas may be provided by more than one gas line in the process chamber. Although not shown in FIG. 6B, an inert gas such as Ar or N₂ may be flowed through the process chamber between deposition cycles. According to one embodiment, a flow rate of the additional CO gas can be greater than the flow of the purge gas.

Methods for area selective deposition (ASD) of metal-containing films using metal carbonyl precursors have been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method for area selective deposition, the method comprising:
providing a substrate in a process chamber, the substrate containing a growth surface and a non-growth surface; and
selectively depositing a metal-containing film on the growth surface relative to the non-grown surface by:
exposing the substrate to a first gas flow containing carbon monoxide (CO) gas to form adsorbed CO on the substrate, and
exposing the substrate to a second gas flow containing a metal carbonyl precursor, wherein the adsorbed CO reduces decomposition rate of the metal carbonyl precursor on the non-growth surface.

2. The method of claim 1, wherein the first gas flow temporally overlaps with the second gas flow.

3. The method of claim 1, wherein exposing the substrate to the first gas flow includes:
initiating the first gas flow; and
stopping the first gas flow prior to initiating the second gas flow.

4. The method of claim 1, wherein a first material contains the non-growth surface and a second material contains the growth surface, and wherein the non-growth surface has a different chemical composition than the growth surface.

5. The method of claim 4, wherein the first material contains a dielectric material or a semiconductor material, and the second material contains a metal or a metal-containing material.

6. The method of claim 1, wherein the selectively depositing further comprises:
exposing the substrate to a third gas flow prior to exposing the substrate to the second gas flow, the third gas flow containing a small molecule inhibitor (SMI) or a self-assembled monolayer precursor.

7. The method of claim 6, wherein the SMI includes hydrogen, hydrazine, oxygen, ammonia, ozone, hydrogen peroxide, water, silane, disilane, trisilane, methane, or mixtures thereof.

8. The method of claim 1, wherein the selectively depositing further comprises:
exposing the substrate to a halogen-containing catalyst that promotes the deposition of metal-containing film on the growth surface.

9. The method of claim 8, wherein the halogen-containing catalyst includes I₂, CH₃I, or C₂H₅I.

10. The method of claim 1, wherein the metal carbonyl precursor includes:
Mₓ(CO)_{y} where M is a metal, x≥1 and y>1; or
Mₓ(CO)_{y}L_{z} where M is a metal, x≥1, y>1, z≥1 and L is a ligand.

11. The method of claim 10, wherein the ligand includes an alkene, a diene, an arene, an ether, an amine, a nitrosyl, a cyanide, a carbene, or a cyclopentadienide.

12. The method of claim 1, wherein the second gas flow containing the metal-carbonyl precursor includes Ru(CO)₅.

13. The method of claim 1, wherein the second gas flow containing the metal-carbonyl precursor includes iron pentacarbonyl (Fe(CO)₅), nickel tetracarbonyl (Ni(CO)₄), manganese hexacarbonyl (Mn₂(CO)₁₀), chromium hexacarbonyl (Cr(CO)₆), tungsten hexacarbonyl (W(CO)₆), molybdenum hexacarbonyl (Mo(CO)₆), cobalt tetracarbonyl (Co(CO)₄), ruthenium pentacarbonyl (Ru(CO)₅), rhodium hexacarbonyl (Rh₆(CO)₁₆), platinum hexacarbonyl (Pt(CO)₆), triruthenium dodecacarbonyl (Ru₃(CO)₁₂), cobalt tricarbonyl nitrosyl (Co(CO)₃(NO), Ru(CO)₃ (1-Methyl-1,4-cyclohexadiene), Ru(CO)₃ (1-Ethyl-1,4-cyclohexadiene), or Ru(CO)₃(1-Propyl-1,4-cyclohexadiene).

14. The method of claim 1, wherein the metal-containing film contains Fe, Ni, Mn, Cr, W, Mo, Co, Ru, Rh, or Pt.

15. The method of claim 1, further comprising: heating the substrate to a temperature between about 30 degrees Celsius and about 550 degrees Celsius.

16. The method of claim 1, further comprising maintaining a gas pressure below about 15 Torr in the process chamber.

17. The method of claim 1, wherein the selectively depositing the metal-containing film is a chemical vapor deposition (CVD) process.

18. The process of claim 1, wherein the selectively depositing the metal-containing film is an atomic layer deposition (ALD) process.

19. A method for area selective deposition, the method comprising:
providing a substrate in a process chamber, the substrate containing a growth surface and a non-growth surface; and
selectively depositing a Ru metal film on the growth surface relative to the non-grown surface by:
exposing the substrate to a first gas flow containing carbon monoxide (CO) gas to form adsorbed CO on the substrate, and exposing the substrate to a second gas flow formed by vaporizing triruthenium dodecacarbonyl (Ru₃(CO)₁₂) in the presence of CO carrier gas, wherein the adsorbed CO reduces decomposition rate of the metal carbonyl precursor on the non-growth surface, and wherein the first gas flow temporally overlaps with or precedes the second gas flow.

20. The method of claim 19, wherein a dielectric material or a semiconductor material contains the non-growth surface and a metal contains the growth surface.
